(19) United States
(12) Patent Application Publication
(10) Pub. No.: US 2023/0328897 A1
(43) Pub. Date: Oct. 12, 2023

(54) MEMBER FOR FORMING WIRING, METHOD FOR FORMING WIRING LAYER USING MEMBER FOR FORMING WIRING, AND WIRING FORMING MEMBER

(71) Applicant: SHOWA DENKO MATERIALS CO., LTD, Tokyo (JP)

(72) Inventors: Hiroyuki IZAWA, Tokyo (JP); Hikari MURAI, Tokyo (JP); Nozomu TAKANO, Tokyo (JP); Kunihiko AKAI, Tokyo (JP); Yuka ITOH, Tokyo (JP); Masashi OHKOSHI, Tokyo (JP)

(21) Appl. No.: 18/019,614

(22) PCT Filed: Aug. 6, 2021
(86) PCT No.: PCT/JP2021/029403

§ 371 Date: Feb. 3, 2023

(30) Foreign Application Priority Data
Aug. 7, 2020 (JP) 2020-135143

(51) Int. Cl. H05K 3/46; H05K 3/38

(52) U.S. Cl. CPC H05K 3/386; H05K 3/4655; H05K 2201/0195

(57) ABSTRACT

A member for forming a wiring includes an adhesive layer and a metal foil layer. The adhesive layer is formed from an adhesive composition including electrically conductive particles. The metal foil layer is disposed on the adhesive layer. In this member for forming a wiring, a ratio of surface roughness Rz of a first surface of the metal foil layer on a side attached to the adhesive layer with respect to an average particle diameter of the electrically conductive particles is 0.05 to 3.

### TECHNICAL FIELD

The present disclosure relates to a member for forming a wiring, a method for forming a wiring layer using a member for forming a wiring, and a wiring forming member.

### BACKGROUND ART

Patent Literature 1 discloses a method for manufacturing a printed wiring board into which an electronic component such as an IC chip is built.

### CITATION LIST

### Patent Literature

Patent Literature 1: Japanese Unexamined Patent Publication No. 2012-191204

### SUMMARY OF INVENTION

### Technical Problem

In a conventional method for manufacturing a substrate with built-in components, as illustrated in FIGS. 7(a) and 7(b), insulating resin layers 102 and 103 are formed on both sides in a lamination direction of an electronic component 101 provided with electrodes 101a. Thereafter, as illustrated in FIGS. 7(c) and 7(d), hole formation by laser, formation of a plated layer, electrode formation by etching, and the like are performed to form via electrodes 104 and 105 reaching each electrode 101a of the electronic component 101 in the insulating resin layers 102 and 103, respectively. Then, as illustrated in FIGS. 8(a) to 8(c), formation of additional insulating resin layers 106 and 107, formation of via electrodes 108 by hole formation by laser and formation of a plated layer, electrode formation by etching, and the like are repeated to form a substrate 110 with built-in components. However, in such a method for manufacturing a substrate with built-in components, one electrically conductive layer (via electrode) is formed by performing lots of treatments, it is necessary to repeat these treatments in order to form a plurality of electrically conductive layers, and thus the manufacturing process is very cumbersome.

In this regard, an adhesive having a metal foil laminated therein and having electrically conductive particles has been studied as a wiring member. However, in the case of simply using an adhesive having a metal foil laminated therein, electrically conductive particles are caught in recesses of the metal foil on the adhesive side, and transformation of the electrically conductive particles into a flat shape during mounting (pressurizing) (conditions under which conduction is stabilized) is not sufficient, and thus conduction is unstable.

In this regard, an object of the present disclosure is to provide a member for forming a wiring, a method for forming a wiring layer using this member for forming a wiring, and a wiring forming member, which can more reliably perform electrical conduction between wirings so as to stabilize the electrical conduction and can simplify a process for forming a wiring layer connecting wirings.

### Solution to Problem

The present disclosure relates to a member for forming a wiring as an aspect. This member for forming a wiring includes an adhesive layer formed from an adhesive composition including electrically conductive particles and a metal foil layer disposed on the adhesive layer. In this member for forming a wiring, a ratio of surface roughness Rz of a surface of the metal foil layer on a side attached to the adhesive layer with respect to an average particle diameter of the electrically conductive particles is 0.05 to 3. Note that, this ratio can be represented as surface roughness Rz/average particle diameter.

In this member for forming a wiring, the ratio of the surface roughness Rz of the surface of the metal foil layer on a side attached to the adhesive layer with respect to the average particle diameter of the electrically conductive particles is 0.05 to 3. Thus, as compared to a case where the ratio of the surface roughness Rz of the surface of the metal foil layer on a side attached to the adhesive layer with respect to the average particle diameter of the electrically conductive particles is more than 3 (see, for example, FIG. 3), the electrically conductive particles can be more reliably crushed into a flat shape to increase the contact area between the electrically conductive particles and the metal foil layer (see, for example, FIG. 4). As a result, electrical conduction between the metal foil layer serving as a wiring pattern or a wiring after processing and another wiring pattern or wiring to which the adhesive layer is attached, can be stabilized. Furthermore, a resistance value in this electrical conduction can be decreased. Furthermore, according to this member for forming a wiring, since the method using an adhesive layer can be realized, as compared to a conventional process in which laser processing, a filled plating treatment, and the like are performed, the process for forming a wiring layer connecting wirings can be simplified.

The present disclosure relates to a member for forming a wiring as another aspect. This member for forming a wiring includes an adhesive layer formed from an adhesive composition including electrically conductive particles and a metal foil layer disposed on the adhesive layer. In this member for forming a wiring, surface roughness Rz of a surface of the metal foil layer on a side attached to the adhesive layer is less than 20 µm.

In this member for forming a wiring, the surface roughness Rz of the surface of the metal foil layer on a side attached to the adhesive layer is less than 20 µm, and the surface roughness of the surface, which is attached to the adhesive layer, of the metal foil layer is decreased. Thus, as compared to a case where the surface roughness of the surface of the metal foil layer on the adhesive layer side is rough (see, for example, FIG. 3), the electrically conductive particles can be more reliably crushed into a flat shape to increase the contact area between the electrically conductive particles and the metal foil layer (see, for example, FIG. 4). As a result, electrical conduction between the metal foil layer serving as a wiring pattern or a wiring after processing and another wiring pattern or wiring to which the adhesive layer is attached, can be stabilized. Furthermore, a resistance value in this electrical conduction can be decreased. Furthermore, according to this member for forming a wiring, since the method using an adhesive layer can be realized, as compared to a conventional process in which laser processing, a filled plating treatment, and the like are performed, the process for forming a wiring layer connecting wirings can be simplified.

In the above member for forming a wiring, the surface roughness Rz of the metal foil layer may be 0.5 µm or more and 10 µm or less. In this case, transformation of the electrically conductive particles into a flat shape by the metal foil layer can be more reliably performed, and electrical conduction between the metal foil layer serving as a wiring pattern or a wiring after processing and another wiring pattern or wiring to which the adhesive layer is attached, can be further stabilized.

In the above member for forming a wiring, an average particle diameter of the electrically conductive particles may be 2 µm or more and 20 µm or less. In this case, the member for forming a wiring itself can be thinned, and at the same time, a wiring layer produced by the member for forming a wiring, a substrate including the wiring layer, and the like can be thinned.

In the above member for forming a wiring, a shortest distance between a surface, which is in contact with the adhesive layer, of the metal foil layer and the surface of the electrically conductive particle may be more than 0 µm and 1 µm or less. In this case, since the electrically conductive particles are disposed on the metal foil layer side, a plurality of electrically conductive particles can be more reliably crushed into a nearly equal flat shape by the metal foil layer. Furthermore, by unevenly distributing the electrically conductive particles on the metal foil side in this way, a retention rate of the electrically conductive particles into a wiring (electrode) or the like is improved so that conduction can also be further stabilized.

In the above member for forming a wiring, the adhesive layer may have a first adhesive layer in which the electrically conductive particles are included in an adhesive component and a second adhesive layer, and the first adhesive layer may by located between the metal foil layer and the second adhesive layer. In this case, since the electrically conductive particles are disposed on the metal foil layer side, a plurality of electrically conductive particles can be more reliably crushed into a nearly equal flat shape by the metal foil layer, so that electrical conductivity can be enhanced. Furthermore, by unevenly distributing the electrically conductive particles on the metal foil side in this way, a retention rate of the electrically conductive particles into a wiring (electrode) or the like is improved so that conduction can be further stabilized. The second adhesive layer can also be an embodiment in which the electrically conductive particles are not included in the adhesive component, and in this case, a portion which has to be insulated can be more reliably insulated. In this case, a member such as a filler may be included in the second adhesive layer.

The above member for forming a wiring may further include a release film. In this case, the member for forming a wiring is easily handled as a member, and working efficiency when a wiring layer is formed using the member for forming a wiring can be improved. For example, the release film can be used by being disposed on a surface of the adhesive layer on a side opposite to the metal foil layer.

The present disclosure relates to a member for forming a wiring, provided with an adhesive layer formed from an adhesive composition including electrically conductive particles and a metal foil layer as separate bodies, the adhesive layer capable of being attached to the metal foil layer during use, as still another aspect. In this member for forming a wiring, a ratio of surface roughness Rz of a surface of the metal foil layer on a side attached to the adhesive layer with respect to an average particle diameter of the electrically conductive particles is 0.05 to 3. In this case, similarly to the above-described case, electrical conduction between the metal foil layer serving as a wiring pattern or a wiring after processing and another wiring pattern or wiring to which the adhesive layer is attached, can be stabilized. Furthermore, a resistance value in this electrical conduction can be decreased. Further, since the adhesive layer and the metal foil layer can be prepared separately (as a set of the member for forming a wiring), working flexibility when a wiring layer is produced using the member for forming a wiring, such as selection of a member for forming a wiring having a more optimal material configuration, can be improved.

The present disclosure relates to a member for forming a wiring, provided with an adhesive layer formed from an adhesive composition including electrically conductive particles and a metal foil layer as separate bodies, the adhesive layer capable of being attached to the metal foil layer during use, as still another aspect. In this member for forming a wiring, surface roughness Rz of a surface of the metal foil layer on a side attached to the adhesive layer is less than 20 µm. In this case, similarly to the above-described case, electrical conduction between the metal foil layer serving as a wiring pattern or a wiring after processing and another wiring pattern or wiring to which the adhesive layer is attached, can be stabilized.

The present disclosure relates to a method for forming a wiring layer using any of the above-described members for forming a wiring, as still another aspect. This method for forming a wiring layer includes: preparing any of the above-described members for forming a wiring; preparing a base material on which a wiring is formed; disposing the member for forming a wiring with respect to a surface of the base material on which a wiring is formed to cover the wiring so that the adhesive layer faces the base material; heating and pressure-bonding the member for forming a wiring to the base material; and subjecting the metal foil layer to a patterning treatment. According to this forming method, the forming process can be considerably simplified as compared to a conventional method. Furthermore, according to this forming method, the formed wiring layer can be easily thinned.

The present disclosure relates to a wiring forming member as still another aspect. This wiring forming member includes a base material having a wiring, and a cured product of any of the above-described members for forming a wiring, the cured product disposed on the base material to cover the wiring. In this wiring forming member, the wiring is electrically connected to the metal foil of the member for forming a wiring or to another wiring formed from the metal foil. According to this aspect, a wiring forming member in which a wiring layer is thinned can be obtained.

### Advantageous Effects of Invention

According to the present disclosure, it is possible to more reliably perform electrical conduction between wirings so as to stabilize the electrical conduction and to simplify a process for forming a wiring layer connecting wirings.

### BRIEF DESCRIPTION OF DRAWINGS

FIG. 1 is a cross-sectional view illustrating a member for forming a wiring according to an embodiment of the present disclosure.

FIGS. 2(a) to 2(d) are views for sequentially describing a method for forming a wiring layer using the member for forming a wiring illustrated in FIG. 1.

FIG. 3 is a cross-sectional view for describing a member for forming a wiring according to Comparative Example and a state where the member for forming a wiring is pressure-bonded.

FIG. 4 is a cross-sectional view for describing the member for forming a wiring according to an embodiment of the present disclosure and a state where the member for forming a wiring is pressure-bonded.

FIGS. 5(a) to (c) are cross-sectional views illustrating members for forming a wiring according to other embodiments of the present disclosure and a state where these members for forming a wiring are pressure-bonded.

FIGS. 6(a) to 6(e) are cross-sectional views sequentially illustrating a conventional method for producing a redistribution layer.

FIGS. 7(a) to 7(d) are cross-sectional views for sequentially describing a conventional method for producing a substrate with built-in components.

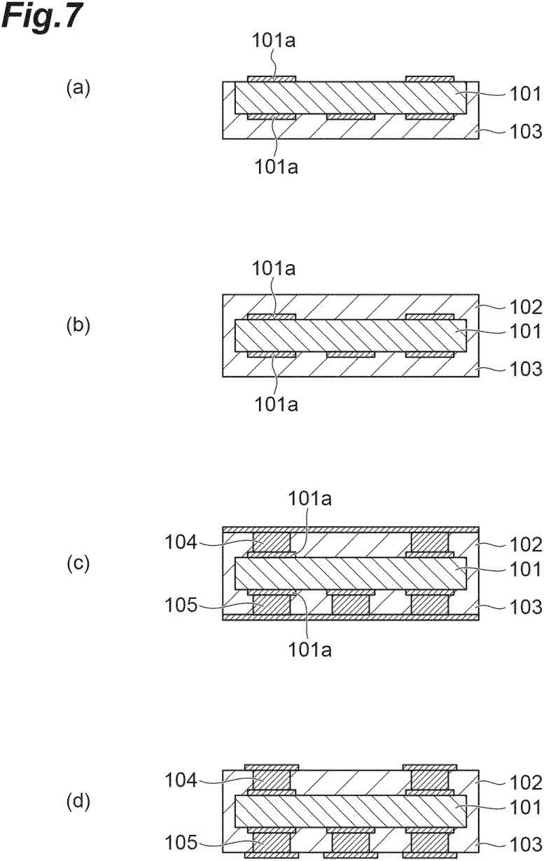

FIGS. 8(a) to 8(c) are cross-sectional views for sequentially describing the conventional method for producing a substrate with built-in components and illustrate steps subsequent to FIG. 7.

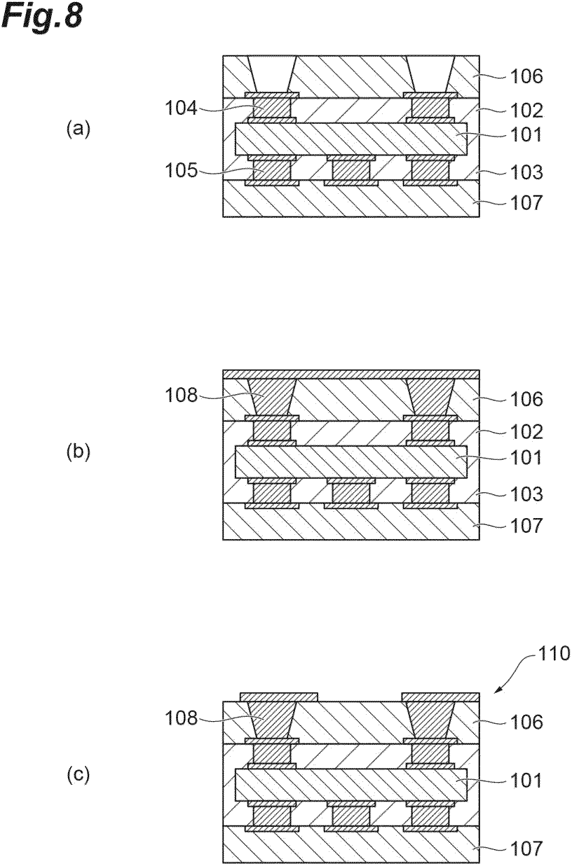

### DESCRIPTION OF EMBODIMENTS

Hereinafter, a member for forming a wiring and a method for forming a wiring layer using the member for forming a wiring according to an embodiment of the present disclosure will be described with reference to the drawings. In the following description, the same or similar portions are denoted with the same reference signs and repeated description is omitted. Furthermore, unless otherwise specified, positional relationships such as top, bottom, right, and left are assumed to be based on positional relationships illustrated in the drawings. Further, dimension ratios in the drawings are not limited to illustrated ratios.

In the present specification, a numerical range expressed by using “to” includes the numerical values before and after “to” as the minimum value and the maximum value, respectively. Furthermore, in a numerical range described in the present specification in a stepwise manner, an upper or lower limit value described in one numerical range may be replaced with an upper or lower limit value in the other numerical range described in a stepwise manner. Furthermore, in a numerical range described in the present specification, an upper or lower limit value of the numerical range may be replaced with a value shown in Examples.

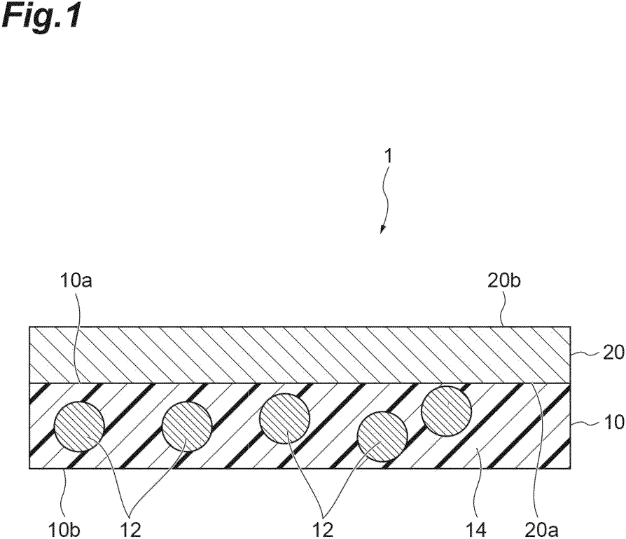

FIG. 1 is a cross-sectional view illustrating a member for forming a wiring according to an embodiment of the present disclosure. As illustrated in FIG. 1, a member 1 for forming a wiring is configured to include an adhesive layer 10 and a metal foil layer 20. The member 1 for forming a wiring is not limited thereto, but is, for example, a member that can be used when a redistribution layer, a build-up multilayer wiring board, a substrate with built-in components, and the like are manufactured. Furthermore, the member 1 for forming a wiring may be used for EMI shield or the like.

The adhesive layer 10 is configured to include electrically conductive particles 12 and an adhesive layer 14 containing an insulating adhesive component in which the electrically conductive particles 12 are dispersed. The adhesive layer 10 has, for example, a thickness of 5 µm to 20 µm. The adhesive component of the adhesive layer 14 is defined as solid contents other than the electrically conductive particles 12. The adhesive layer 14 may be in a B-stage state where the surface is dried before the formation of a wiring layer by the member 1 for forming a wiring is performed, that is, may be in a semi-cured state.

### Configuration of Electrically Conductive Particles

The electrically conductive particles 12 are substantially spherical particles having electrical conductivity, and are configured by metal particles configured by metals such as Au, Ag, Ni, Cu, and solder, electrically conductive carbon particles configured by electrically conductive carbon, or the like. The electrically conductive particles 12 may be coated electrically conductive particles each including a core which includes non-conductive glass, ceramic, plastic (such as polystyrene), or the like, and a coating layer which includes the metal or the electrically conductive carbon described above and covers the core. Among these, the electrically conductive particles 12 may be coated electrically conductive particles each including a core which includes metal particles formed from hot-melt metals or plastic, and a coating layer which includes the metal or the electrically conductive carbon and covers the core.

In an embodiment, the electrically conductive particle 12 includes a core including polymer particles such as polystyrene (plastic particles) and a metal layer covering the core. In the polymer particle, substantially the entire surface thereof may be covered with the metal layer, and a part of the surface of the polymer particle may be exposed without being covered with the metal layer as long as the function as a connection material is maintained. The polymer particles may be, for example, particles each containing a polymer including at least one monomer selected from styrene and divinylbenzene as a monomer unit.

The metal layer may be formed from various metals such as Ni, Ni/Au, Ni/Pd, Cu, NiB, Ag, and Ru. The metal layer may be an alloy layer composed of an alloy of Ni and Au, an alloy of Ni and Pd, or the like. The metal layer may have a multilayer structure including a plurality of metal layers. For example, the metal layer may include an Ni layer and an Au layer. The metal layer may be produced by plating, vapor deposition, sputtering, soldering, or the like. The metal layer may be a thin film (for example, a thin film formed by plating, vapor deposition, sputtering, or the like).

The electrically conductive particle 12 may have an insulating layer. Specifically, for example, an insulating layer further covering the coating layer may be provided on the outer side of the coating layer in the electrically conductive particles of the above-described embodiment each including the core (for example, the polymer particle) and the coating layer, such as a metal layer, covering the core. The insulating layer may be an outermost surface layer located on the outermost surface of the electrically conductive particle. The insulating layer may be a layer formed from an insulating material such as silica or an acrylic resin.

An average particle diameter Dp of the electrically conductive particles 12 may be 1 µm or more, may be 2 µm or more, and may be 5 µm or more, from the viewpoint of excellent dispersibility and electrical conductivity. The average particle diameter Dp of the electrically conductive particles may be 50 µm or less, may be 30 µm or less, and may be 20 µm or less, from the viewpoint of excellent dispersibility and electrical conductivity. From the above-described viewpoint, the average particle diameter Dp of the electrically conductive particles may be 1 to 50 µm, may be 5 to 30 µm, may be 5 to 20 µm, and may be 2 to 20 µm.

A maximum particle diameter of the electrically conductive particles 12 may be smaller than the minimum interval between electrodes in the wiring pattern (the shortest distance between electrodes adjacent to each other). The maximum particle diameter of the electrically conductive particles 12 may be 1 µm or more, may be 2 µm or more, and may be 5 µm or more, from the viewpoint of excellent dispersibility and electrical conductivity. The maximum particle diameter of the electrically conductive particles may be 50 µm or less, may be 30 µm or less, and may be 20 µm or less, from the viewpoint of excellent dispersibility and electrical conductivity. From the above-described viewpoint, the maximum particle diameter of the electrically conductive particles may be 1 to 50 µm, may be 2 to 30 µm, and may be 5 to 20 µm.

In the present specification, the particle diameters of randomly selected 300 (pcs) particles are measured by observation using a scanning electron microscope (SEM), and the average value of the particle diameters thus obtained is regarded as the average particle diameter Dp, and the largest value thus obtained is regarded as the maximum particle diameter of the particles. In a case where the shape of the particle is not a spherical shape, for example, the particle has a projection, the particle diameter of the particle is a diameter of a circle circumscribing the particle in an SEM image.

The content of the electrically conductive particles 12 is determined according to the fineness of an electrode to be connected, or the like. For example, the blended amount of the electrically conductive particles 12 is not particularly limited, and may be 0.1% by volume or more, and may be 0.2% by volume or more, on the basis of the total volume of the adhesive components (components excluding the electrically conductive particles in the adhesive composition). When the blended amount is 0.1% by volume or more, there is a tendency that a decrease in electrical conductivity is suppressed. The blended amount of the electrically conductive particles 12 may be 30% by volume or less, and may be 10% by volume or less, on the basis of the total volume of the adhesive components (components excluding the electrically conductive particles 12 in the adhesive composition). When the blended amount is 30% by volume or less, there is a tendency that short circuit of a circuit hardly occurs. Note that, “volume percentage” is determined based on the volume of each component before curing at 23° C., and the volume of each component can be converted into the volume from the weight by using the specific weight. Furthermore, the volume of the component can also be determined as the increased volume resulting after loading the component into a graduated cylinder or the like containing a suitable solvent (water, alcohol, or the like) that sufficiently wets the components, without dissolving or swelling the component.

### Configuration of Adhesive Layer/Adhesive Component

The adhesive component constituting the adhesive layer 14 may contain a curing agent, a monomer, and a film forming material. In the case of using an epoxy resin monomer, as a curing agent, an imidazole-based agent, a hydrazide-based agent, a boron trifluoride-amine complex, a sulfonium salt, aminimide, a polyamine salt, dicyandiamide, and the like can be used. When the curing agent is covered with a polyurethane-based or polyester-based high-molecular material or the like to be microencapsulated, the pot life is extended, which is preferable. On the other hand, in the case of using an acrylic monomer, as a curing agent, those which are decomposed by heating to generate free radicals, such as a peroxide compound and an azo-based compound, can be used.

A curing agent in the case of using an epoxy monomer is appropriately selected according to a target connection temperature, connection time, storage stability, and the like. The curing agent may be a curing agent having a gelation time with an epoxy resin composition at a predetermined temperature of 10 seconds or shorter from the viewpoint of high reactivity, and may be a curing agent having no change in gelation time with an epoxy resin composition after storage in a thermostat bath at 40° C. for 10 days from the viewpoint of storage stability. From such viewpoints, the curing agent may be a sulfonium salt.

A curing agent in the case of using an acrylic monomer is appropriately selected according to a target connection temperature, connection time, storage stability, and the like. From the viewpoint of high reactivity and storage stability, the curing agent may be an organic peroxide or an azo-based compound with a 10 hour half-life temperature of 40° C. or higher and a 1 minute half-life temperature of 180° C. or lower, and may be an organic peroxide or an azo-based compound with a 10 hour half-life temperature of 60° C. or higher and a 1 minute half-life temperature of 170° C. or lower. These curing agents can be used alone or used as a mixture thereof, and may be used by mixing a decomposition accelerator, an inhibitor, or the like.

Even in the case of using any of an epoxy monomer and an acrylic monomer, in a case where the connection time is set to 10 seconds or shorter, in order to obtain a sufficient reaction rate, the blended amount of the curing agent may be 0.1 parts by mass to 40 parts by mass and may be 1 part by mass to 35 parts by mass, with respect to 100 parts by mass of the total of a monomer described below and a film forming material described below. When the blended amount of the curing agent is less than 0.1 parts by mass, there are tendencies that a sufficient reaction rate cannot be obtained, and a favorable bonding strength or a small connection resistance is less likely to be obtained. On the other hand, when the blended amount of the curing agent is more than 40 parts by mass, there are tendencies that the fluidity of the adhesive is decreased, the connection resistance is increased, or the storage stability of the adhesive is decreased.

Furthermore, in the case of using an epoxy resin monomer, as a monomer, a bisphenol type epoxy resin induced from epichlorohydrin and bisphenol A, bisphenol F, bisphenol AD, or the like, an epoxy novolac resin induced from epichlorohydrin and phenol novolac or cresol novolac, various types of epoxy compounds of glycidyl amine, glycidyl ether, biphenyl, alicyclic, and the like having two or more glycidyl groups in one molecule, and the like can be used.

In the case of using an acrylic monomer, a radical polymerizable compound may be a substance having a functional group that is polymerized by radicals. Examples of such a radical polymerizable compound include (meth)acrylate, a maleimide compound, and a styrene derivative. Furthermore, the radical polymerizable compound can also be used in any state of a monomer and an oligomer, and a monomer and an oligomer may be used as a mixture. These monomers may be used alone or as a mixture of two or more kinds thereof.

The film forming material is a polymer having an action of facilitating the handling of a low-viscosity composition containing the curing agent and the monomer described above. By using the film forming material, the film is prevented from being easily torn, being broken, or becoming sticky, and thus the adhesive layer 10 which is easily handled is obtained.

As the film forming material, a thermoplastic resin is preferably used, and examples thereof include a phenoxy resin, a polyvinyl formal resin, a polystyrene resin, a polyvinyl butyral resin, a polyester resin, a polyamide resin, a xylene resin, a polyurethane resin, a polyacrylic resin, and a polyester urethane resin. Further, in these polymers, a siloxane bond or a fluorine substituent may be contained. These resins can be used alone or as a mixture of two or more kinds thereof. Among the above-described resins, from the viewpoint of a bonding strength, compatibility, heat resistance, and a mechanical strength, a phenoxy resin may be used.

As the molecular weight of the thermoplastic resin increases, film formability is easily obtained, and a melt viscosity affecting the fluidity of the film can be set in a wide range. The molecular weight of the thermoplastic resin may be 5000 to 150000, and may be 10000 to 80000 in terms of weight average molecular weight. By setting the weight average molecular weight to 5000 or more, favorable film formability is easily obtained, and by setting the weight average molecular weight to 150000 or less, favorable compatibility with other components is easily obtained.

In the present disclosure, the weight average molecular weight refers to a value measured using a calibration curve prepared using standard polystyrene by gel permeation chromatograph (GPC) according to the following conditions.

### Measurement Conditions

Apparatus: GPC-8020 manufactured by Tosoh Corporation
Detector: RI-8020 manufactured by Tosoh Corporation
Column: Gelpack GLA160S + GLA150S manufactured by Hitachi Chemical Co., Ltd.
Sample concentration: 120 mg/3 mL
Solvent: Tetrahydrofuran
Injection amount: 60 µL
Pressure: 2.94 × 106 Pa (30 kgf/cm²)
Flow rate: 1.00 mL/min

Furthermore, the content of the film forming material may be 5% by weight to 80% by weight and may be 15% by weight to 70% by weight, on the basis of the total amount of the curing agent, the monomer, and the film forming material. When the content thereof is set to 5% by weight or more, there is a tendency that favorable film formability is easily obtained, and when the content thereof is set to 80% by weight or less, there is a tendency that a curable composition exhibits favorable fluidity.

Furthermore, the adhesive layer forming the adhesive layer 10 may further contain a filler, a softener, an accelerator, an antioxidant, a colorant, a flame retardant, a thixotropic agent, a coupling agent, a phenolic resin, a melamine resin, isocyanates, and the like.

In the case of containing a filler, the improvement of connection reliability can be further expected. The maximum diameter of the filler may be less than the particle diameter of the electrically conductive particle 12, and the content of the filler may be 5 parts by volume to 60 parts by volume with respect to 100 parts by volume of the adhesive layer. When the content of the filler is 5 parts by volume to 60 parts by volume, there is a tendency that favorable connection reliability is obtained.

### Configuration of Metal Foil Layer

The surface roughness Rz of each of one surface of the metal foil layer 20 and the opposite surface may be the same, and may be different. The metal foil layer 20 has, for example, a thickness of 5 µm to 200 µm. The thickness of the metal foil layer described herein refers to the thickness including the surface roughness Rz. The metal foil layer 20 is, for example, a copper foil, an aluminum foil, a nickel foil, stainless steel, titanium, or platinum.

The adhesive layer 10 is disposed on a first surface 20a of the metal foil layer 20. The surface roughness Rz of the first surface 20a of the metal foil layer 20 may be 0.3 µm or more, may be 0.5 µm or more, and may be 1.0 µm or more. Furthermore, the surface roughness Rz of the first surface 20a of the metal foil layer 20 may be 50 µm or less, may be 40 µm or less, may be 30 µm or less, may be 20 µm or less, may be less than 20 um, may be 17 µm or less, may be 10 µm or less, may be 8.0 µm or less, may be 5.0 µm or less, and may be 3.0 µm or less. The surface roughness Rz of the first surface 20a of the metal foil layer 20 may be, for example, 0.3 µm or more and 20 µm or less, may be 0.3 µm or more and less than 20 µm, and more specifically, may be 0.5 µm or more and 10 µm or less. Note that, the surface roughness Rz of a second surface 20b of the metal foil layer 20 may be, for example, 20 µm or more, may be rougher than the surface roughness Rz of the first surface 20a, may be the same as the surface roughness of the first surface 20a, and may not be rougher than the surface roughness Rz of the first surface 20a. In a case where the surface roughness Rz of the first surface 20a of the metal foil layer 20 is too smooth (for example, the surface roughness Rz is 0.2 µm), adhesiveness between the metal foil layer 20 and the adhesive layer 10 cannot be maintained over a long period of time, and the layers may be peeled off from each other. Thus, the surface roughness Rz of the first surface 20a of the metal foil layer 20 may be 0.3 µm or more. However, by employing a material or a connection configuration that can secure adhesiveness, the surface roughness Rz of the first surface 20a of the metal foil layer 20 may be less than 0.3 µm.

The surface roughness Rz means ten-point average roughness Rzjis as measured according to the method defined in JIS standard (JIS B 0601-2001), and refers to a value as measured using a commercially available surface roughness state measuring machine. For example, the surface roughness can be measured using a nano search microscope (“SFT-3500” manufactured by SHIMADZU CORPORATION).

Herein, a relation between the average particle diameter Dp of the electrically conductive particles 12 and the surface roughness Rz of the first surface 20a of the metal foil layer 20 will be described below. In the present embodiment, a ratio of the surface roughness Rz of the first surface 20a of the metal foil layer 20 with respect to the average particle diameter Dp of the electrically conductive particles 12, that is, “surface roughness/average particle diameter” may be 0.03 or more, may be 0.04 or more, may be 0.05 or more, may be 0.06 or more, may be 0.1 or more, may be 0.2 or more, may be 0.3 or more, may be 0.5 or more, and may be 1 or more. Furthermore, the ratio of the surface roughness Rz of the first surface 20a of the metal foil layer 20 with respect to the average particle diameter Dp of the electrically conductive particles 12, that is, “surface roughness/average particle diameter” may be 3 or less, may be 2 or less, may be 1.7 or less, and may be 1.5 or less. The ratio of the surface roughness Rz of the first surface 20a of the metal foil layer 20 with respect to the average particle diameter Dp of the electrically conductive particles 12, that is, “surface roughness/average particle diameter” may be, for example, 0.05 or more and 3 or less, and more specifically, may be 0.06 or more and 2 or less. In the present embodiment, the surface roughness Rz of the first surface 20a of the metal foil layer 20 and the average particle diameter Dp of the electrically conductive particles 12 are managed so that the ratio of the surface roughness Rz of the first surface 20a of the metal foil layer 20 with respect to the average particle diameter Dp of the electrically conductive particles 12, that is, “surface roughness/average particle diameter” is in a range of 0.05 to 3.

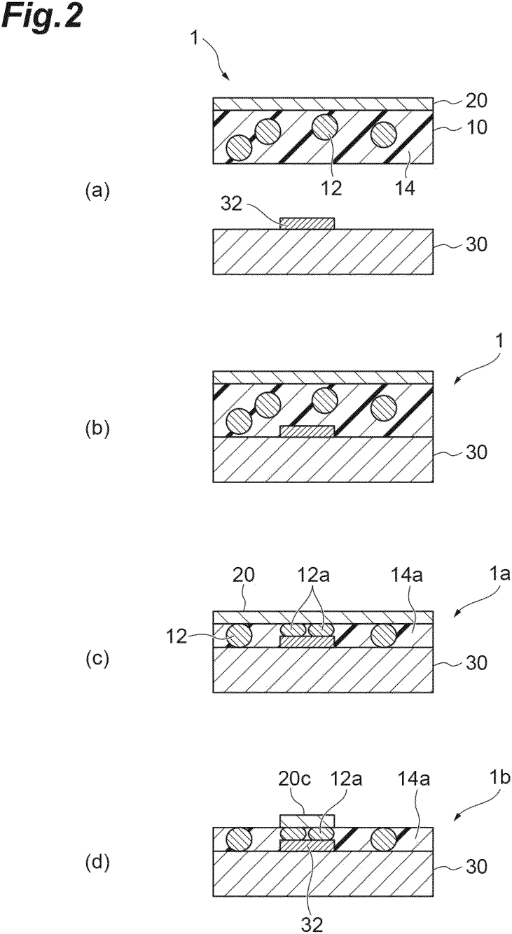

The present disclosure relates to a method for forming a wiring layer using the member for forming a wiring, as another aspect. The method for forming a wiring layer using the aforementioned member 1 for forming a wiring will be described with reference to FIG. 2. FIGS. 2(a) to 2(d) are views illustrating a method for forming a wiring layer using the member for forming a wiring illustrated in FIG. 1.

First, as illustrated in FIG. 2(a), the member 1 for forming a wiring is prepared. Further, a base material 30 on which a wiring 32 is formed is prepared. Then, the member 1 for forming a wiring is disposed so that the adhesive layer 10 side of the member 1 for forming a wiring faces the base material 30. Thereafter, as illustrated in FIG. 2(b), lamination is performed so as to cover the wiring 32, and thus the member 1 for forming a wiring is bonded onto the base material 30.

Subsequently, as illustrated in FIG. 2(c), predetermined heating and pressurization are performed with respect to the member 1 for forming a wiring to perform pressure-bonding with respect to the base material 30. At this time, since the first surface 20a of the metal foil layer 20 of the member 1 for forming a wiring is flat, the electrically conductive particles 12 required to secure electrical conductivity can be more reliably transformed into electrically conductive particles 12a having a flat shape. Then, in a pressure-bonded member 1a for forming a wiring, the electrically conductive particles 12a flattened on the wiring 32 (as a result, the insulating layer is broken to expose a conductive portion) are disposed, and reliable electrical conduction between the metal foil layer 20 and the wiring 32 is achieved. At this time, the adhesive layer 14 is also crushed to form a thinner adhesive layer 14a.

Subsequently, as illustrated in FIG. 2(d), the metal foil layer 20 is subjected to a predetermined patterning treatment (for example, an etching treatment) and is processed into a predetermined wiring pattern 20c (another wiring). At this time, the second surface 20b of the metal foil layer 20 may be subjected to a treatment to have a smooth surface. The aforementioned treatments of FIGS. 2(a) to 2(d) may be repeated for a predetermined number of times to form a wiring layer.

That is, the method for forming a wiring layer using the member for forming a wiring includes: preparing the member for forming a wiring; preparing a base material on which a wiring is formed; disposing the member for forming a wiring with respect to a surface of the base material on which a wiring is formed to cover the wiring so that the adhesive layer side faces the substrate; heating and pressure-bonding the member for forming a wiring to the base material; and subjecting the metal foil layer to a patterning treatment.

By the above steps, a wiring forming member lb is formed. This wiring forming member lb includes the base material 30 having the wiring 32, and a cured product of the member 1 for forming a wiring (heated and pressure-bonded member for forming a wiring), the cured product disposed on the base material 30 to cover the wiring 32. In this wiring forming member 1b, the wiring 32 is electrically connected to the metal foil 20 of the member 1 for forming a wiring or to a wiring 20c formed from the metal foil 20 (for example, etching processing) by the electrically conductive particles 12a. In the case of repeating the treatments of FIGS. 2(a) to 2(d) for a predetermined number of times, the wiring forming member 1b may have a configuration having a plurality of wiring layers (layers connecting wirings described above).

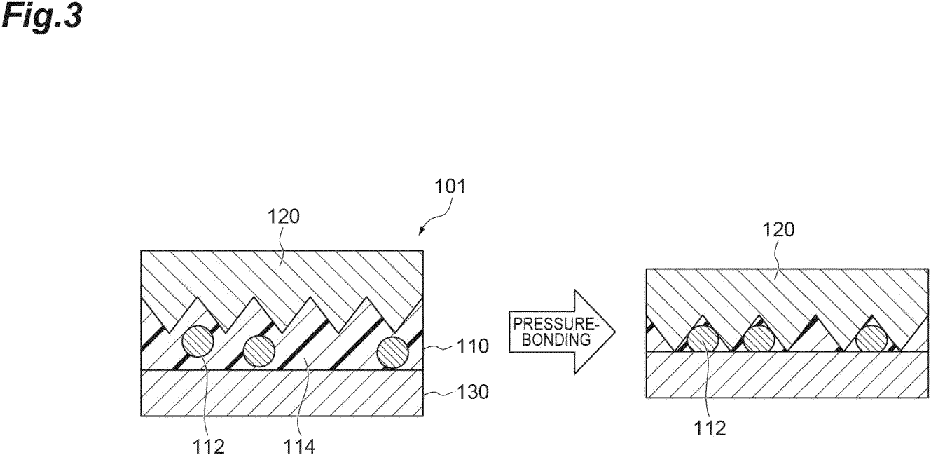

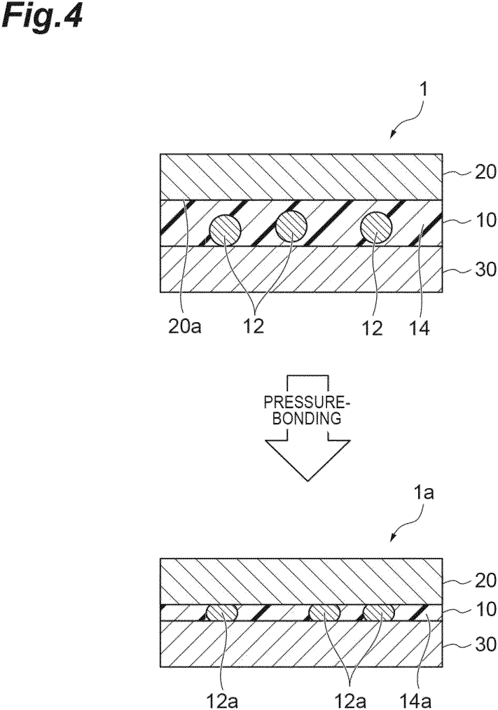

Herein, with reference to FIG. 3 and FIG. 4, description on which conduction in the member 1 for forming a wiring by the electrically conductive particles 12 and 12a is stabilized will be made. FIG. 3 is a cross-sectional view for describing a member 101 for forming a wiring according to Comparative Example and a state where the member 101 for forming a wiring is pressure-bonded. FIG. 4 is a cross-sectional view for describing the member 1 for forming a wiring according to an embodiment of the present disclosure and a state where the member 1 for forming a wiring is pressure-bonded.

As illustrated in FIG. 3, in a case where a metal foil layer 120 of the member 101 for forming a wiring according to Comparative Example is disposed so that a matte surface having rough surface roughness (referred to as surface roughness Rz1) faces an adhesive layer 110, a case where a ratio of the surface roughness Rz1 of the matte surface of the metal foil layer 120 with respect to the average particle diameter Dp of electrically conductive particles 112, that is, “surface roughness/average particle diameter” is more than 3 is considered. When pressure-bonding is performed in such a case, as illustrated in the drawing (right drawing) after the pressure-bonding, the electrically conductive particles 112 may enter into recesses of irregularities of the matte surface of the metal foil layer 120. In this case, since the electrically conductive particles 112 have still a shape close to a grain shape without being crushed by the metal foil layer 120 to have a flat shape, the contact area is still small. Furthermore, in a case where the electrically conductive particle 112 has an insulating layer on the outermost layer, the insulating layer is not sufficiently broken. Thus, in such a member 1 for forming a wiring according to Comparative Example, conduction between wirings is not stabilized.

On the other hand, as illustrated in FIG. 4, in the member 1 for forming a wiring, since the first surface 20a of the metal foil layer 20 is disposed to face the adhesive layer 10 side, the electrically conductive particles 12 are more reliably crushed at the time of pressure-bonding, and thus can be transformed into a desired flat surface. Furthermore, even in a case where the electrically conductive particle 12 has an insulating layer on the outermost layer, since the electrically conductive particles 12 are sufficiently crushed, the insulating layer can be broken to expose a conductive portion thereinside. In the case, since an area at which the conductive portions of the electrically conductive particles 12a are in contact with the metal foil layer 20 and another wiring can be sufficiently and widely secured, conduction between wirings can be more reliably stabilized.

As described above, with the member 1 for forming a wiring according to the present embodiment, the ratio of the surface roughness Rz of the first surface 20a of the metal foil layer 20 on a side attached to the adhesive layer 10 with respect to the average particle diameter of the electrically conductive particles 12 is 0.05 to 3. Thus, as compared to a case where the ratio of the surface roughness Rz1 of the matte surface of the metal foil layer 120 with respect to the average particle diameter Dp of the electrically conductive particles 112 according to Comparative Example, that is, “surface roughness/average particle diameter” is more than 3 (see FIG. 3), the electrically conductive particles 12 and 12a can be more reliably crushed into a flat shape to increase the contact area between the electrically conductive particles 12 and 12a and the metal foil layer 20 (see FIG. 4). As a result, electrical conduction between the metal foil layer 20 serving as a wiring pattern or a wiring after processing and another wiring pattern or wiring to which the adhesive layer 10 is attached, can be stabilized. Furthermore, according to this member 1 for forming a wiring, since the method using an adhesive layer can be realized, as compared to a conventional process, the process for forming a wiring layer connecting wirings can be simplified.

In the member 1 for forming a wiring, the surface roughness Rz of the first surface 20a of the metal foil layer 20 may be less than 20 µm, and may be 0.5 µm or more and 10 µm or less. In this case, since transformation of the electrically conductive particles 12 into a flat shape by the first surface 20a of the metal foil layer 20 can be more reliably performed, electrical conduction between the metal foil layer 20 serving as a wiring pattern or a wiring after processing and another wiring pattern or wiring to which the adhesive layer 10 is attached, can be more reliably stabilized.

In the member 1 for forming a wiring, the average particle diameter of the electrically conductive particles 12 may be 2 µm or more and 20 µm or less. In this case, the member 1 for forming a wiring itself can be thinned, and at the same time, a wiring layer produced by the member 1 for forming a wiring, a substrate including the wiring layer, and the like can be thinned.

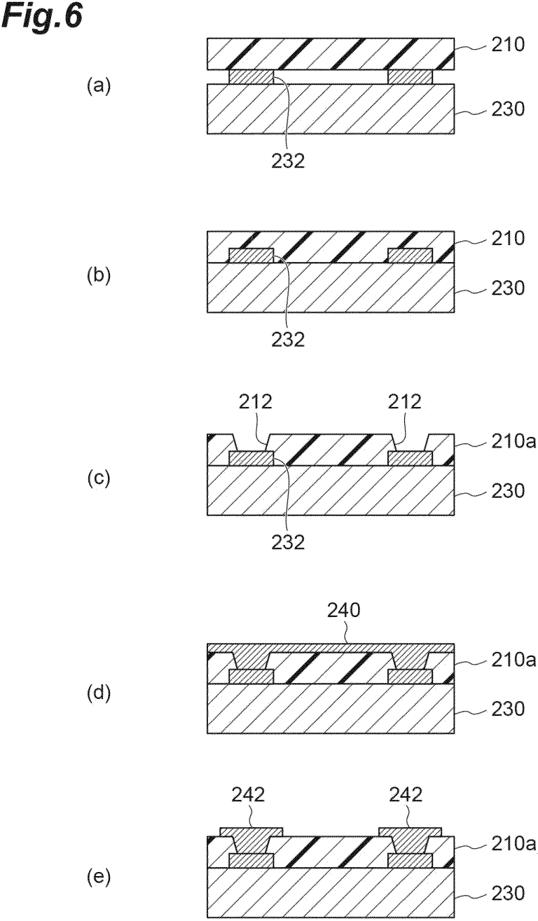

Furthermore, in the method for forming a wiring layer using the member 1 for forming a wiring, the forming process can be considerably simplified as compared to a conventional method (see FIG. 6). Furthermore, according to this forming method, the formed wiring layer can be easily thinned.

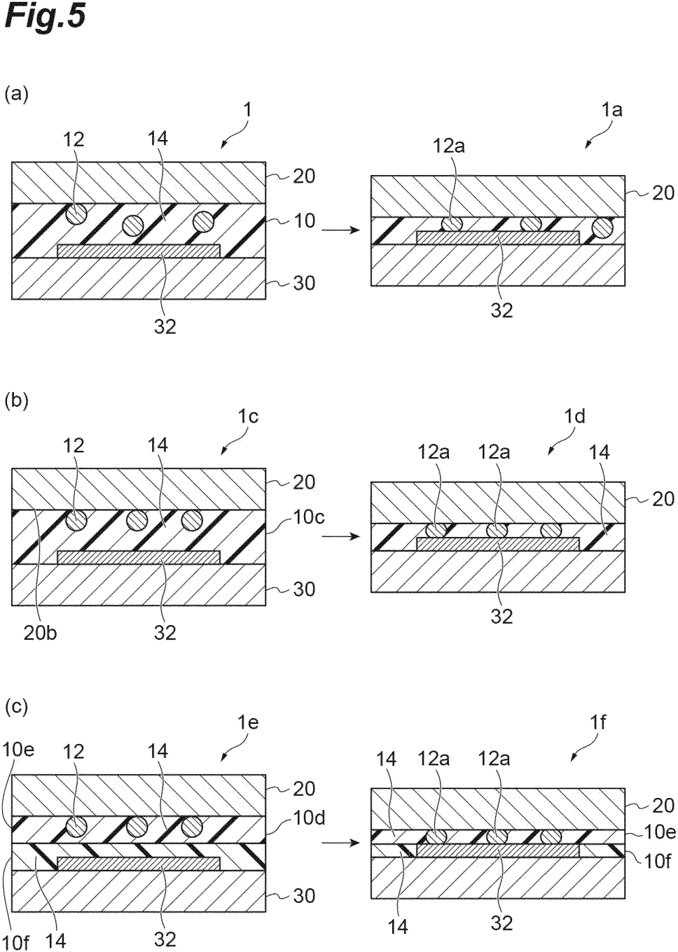

Hereinbefore, embodiments of the present disclosure have been described in detail, but the present disclosure is not limited to the above-described embodiments and can be applied to various embodiments. For example, in the above-described embodiment, as illustrated in FIG. 5(a), the member 1 for forming a wiring has a configuration in which the electrically conductive particles 12 are randomly or averagely dispersed in the adhesive layer 10, but as illustrated in FIG. 5(b), a configuration in which the electrically conductive particles 12 are disposed (unevenly distributed) on the metal foil layer 20 side may be employed. In this case, in the adhesive layer 10, the electrically conductive particles 12 are not exposed on a second surface 10b on a side opposite to the metal foil layer 20, and the thickness of the adhesive layer 10 existing between the electrically conductive particles 12 and the first surface 20a of the metal foil layer 20 may be 0 µm, or more than 0.1 µm and 1 µm or less. In this case, since the electrically conductive particles 12 are disposed on the metal foil layer 20 side, in a wiring layer 1d, the electrically conductive particles 12 can be more reliably crushed into a flat shape by the metal foil layer 20. Furthermore, by unevenly distributing the electrically conductive particles 12 on the metal foil layer 20 side in this way, a retention rate of the electrically conductive particles 12 into a wiring (electrode) or the like can be improved. That is, conduction can be more stabilized. The aforementioned distance between the electrically conductive particles 12 and the first surface 20a of the metal foil layer 20 (the thickness of the adhesive layer 10 existing therebetween) means the shortest distance between the surface of the metal foil layer 20 in contact with the adhesive layer 10 and the surface of the electrically conductive particle 12, and is, for example, an average value of randomly selected 30 points. Furthermore, this distance is measured in such a manner that the member for forming a wiring is interposed between two sheets of glass (thickness: about 1 mm) and cast with a resin composition composed of 100 g of a bisphenol A type epoxy resin (trade name: JER811, manufactured by Mitsubishi Chemical Corporation) and 10 g of a curing agent (trade name: Epomount Curing Agent, manufactured by Refine Tec Ltd.), the cross section is then polished using a polishing machine, and the distance is measured using a scanning electron microscope (SEM, trade name: SE-8020, manufactured by Hitachi High-Tech Science Corporation).

Furthermore, as illustrated in FIG. 5(c), an adhesive layer 10d may be formed while being divided into a first adhesive layer 10e and a second adhesive layer 10f. The adhesive component constituting the first adhesive layer 10e and the second adhesive layer 10f may be the same as the adhesive component constituting the aforementioned adhesive layer 10, but is different from the adhesive component constituting the adhesive layer 10 in that the electrically conductive particles 12 are not dispersed in the second adhesive layer 10f, that is, are not included. In a member 1e for forming a wiring according to this modification example, the electrically conductive particles 12 are dispersed in the first adhesive layer 10e, that is, are included. In this case, similarly to the modification example illustrated in FIG. 5(b), since the electrically conductive particles 12 are disposed on the metal foil layer 20 side, in a wiring layer 1f, the electrically conductive particles 12 can be more reliably crushed into a flat shape by the metal foil layer 20. Furthermore, by unevenly distributing the electrically conductive particles 12 on the metal foil layer 20 side in this way, the retention rate of the electrically conductive particles 12 into a wiring (electrode) or the like can be improved. That is, conduction can be more stabilized.

Furthermore, in the members 1, 1c, and le for forming a wiring, a release film may be provided. The release film may be attached onto a side opposite to the surface of each of the adhesive layers 10, 10c, and 10d to which the metal foil layer 20 is attached, and may be attached onto a side opposite to the surface of the metal foil layer 20 to which each of the adhesive layers 10, 10c, and 10d is attached. Furthermore, the first surface 20a of the metal foil layer 20 may be attached to each of the adhesive layers 10, 10c, and 10d. In this case, the member for forming a wiring is easily handled, and working efficiency when a wiring layer is formed using the member for forming a wiring can be improved.

Furthermore, in the above description, a case where the member for forming a wiring is a member to which the adhesive layer 10 and the metal foil layer 20 are attached has been described as an example, but the member for forming a wiring in the present embodiment may be provided with the adhesive layer 10 and the metal foil layer 20 as separate bodies, and may be configured as a set product in which the adhesive layer 10 can be attached to the first surface 20a of the metal foil layer 20 during use. In this case, since the adhesive layer 10 and the metal foil layer 20 can be prepared separately (as a set of the member for forming a wiring), working flexibility when a wiring layer is produced using the member for forming a wiring, such as selection of a member for forming a wiring having a more optimal material configuration, can be improved.

### EXAMPLES

Hereinafter, the present disclosure will be more specifically described by means of Examples. However, the present disclosure is not limited to these Examples.

### Preparation of Member for Forming Wiring

Respective materials for producing an electrically conductive adhesive layer and an insulating adhesive layer were prepared as described below.

### Preparation of Thermoplastic Resin

As a thermoplastic resin, a phenoxy resin (trade name: FX-316, manufactured by Nippon Steel Chemical Co., Ltd.) was prepared.

### Synthesis of Acrylic Rubber

In a polymerizing reactor equipped with a thermometer and a stirrer, 200 parts of water, 2 parts of sodium lauryl sulfate, 29.25 parts by mass of ethyl acrylate (EA: manufactured by Aldrich Co.), 39.25 parts by mass of butyl acrylate (BA, manufactured by Aldrich Co.), acrylonitrile (AN, manufactured by Aldrich Co.), and 3 parts by mass of glycidyl methacrylate (GMA, manufactured by Aldrich Co.) were charged, deaeration under reduced pressure and substitution of the atmosphere with nitrogen were conducted three times to sufficiently remove oxygen, and then emulsion polymerization was performed at 30° C. for 5 hours under normal pressure. The obtained emulsion polymerization solution was solidified by an aqueous calcium chloride solution, and then washed with water and dried to obtain acrylic rubber.

### Preparation of Latent Curing Agent

As a latent curing agent, a master batch type latent curing agent (trade name: Novacure 3941, activating temperature: 125° C., manufactured by Asahi Chemical Industry Co., Ltd.) obtained by dispersing a microcapsule type curing agent having an average particle diameter of 5 µm, which has an imidazole modified product as a core with a surface thereof covered with polyurethane, in a liquid bisphenol F type epoxy resin, was prepared.

### Preparation of Electrically Conductive Particles A1

As electrically conductive particles A1, a nickel layer having a thickness of 0.2 µm was provided on the surface of a particle having polystyrene as a core, and a metal layer having a thickness of 0.02 µm was provided on the outer side of this nickel layer to prepare electrically conductive particles having an average particle diameter of 5 µm and a specific weight of 2.3.

### Preparation of Electrically Conductive Particles A2

As electrically conductive particles A2, a nickel layer having a thickness of 0.2 µm was provided on the surface of a particle having polystyrene as a core, and a metal layer having a thickness of 0.02 µm was provided on the outer side of this nickel layer to prepare electrically conductive particles having an average particle diameter of 10 µm and a specific weight of 2.1.

### Preparation of Electrically Conductive Particles A3

As electrically conductive particles A3, a nickel layer having a thickness of 0.2 µm was provided on the surface of a particle having polystyrene as a core, and a metal layer having a thickness of 0.02 µm was provided on the outer side of this nickel layer to prepare electrically conductive particles having an average particle diameter of 3 µm and a specific weight of 2.5.

### Preparation of Electrically Conductive Particles B

As electrically conductive particles B, Ni particles having an average particle diameter of 4 µm and an apparent density of 2.1 g/cm³ were prepared.

### Example 1

After 20 parts by mass of a phenoxy resin (FX-316 manufactured by Nippon Steel Chemical Co., Ltd.), 20 parts by mass of acrylic rubber (ACM), and 60 parts by mass of a latent curing agent “Novacure 3941” were dissolved in 100 parts by mass of toluene, electrically conductive particles shown in Table 1 were added thereto to prepare a coating liquid for forming an adhesive layer.

This coating liquid was applied onto one surface (a surface to be applied with the coating liquid) of a copper foil shown in Table 1 by using a coating apparatus (manufactured by Yasui Seiki Company, Ltd., product name: Precision Coating Machine) and dried with hot air at 70° C. for 10 minutes to produce an adhesive film having a thickness of 18 µm on the copper foil. The surface roughness Rz shown in Table 1 refers to surface roughness in the surface of the copper foil on the adhesive film side.

### Examples 2 to 13 and Comparative Examples 1 to 4

Each adhesive film was produced on a copper foil by the same method as in Example 1, except that the type and the number of blended parts of electrically conductive particles, and the surface roughness and the thickness of the copper foil were changed as shown in Table 1.

TABLE 1

| | Type of electrically conductive particles | Particle diameter (µm) | Number of blended parts | Surface roughness Rz (µm) | Copper foil thickness (µm) |
|---|---|---|---|---|---|
| Example 1 | Electrically conductive particles A2 | 10 | 4 | 0.6 | 18 |
| Example 2 | Electrically conductive particles A2 | 10 | 4 | 2.5 | 18 |
| Example 3 | Electrically conductive particles A2 | 10 | 4 | 5.0 | 18 |
| Example 4 | Electrically conductive particles A1 | 5 | 4 | 0.6 | 18 |
| Example 5 | Electrically conductive particles A1 | 5 | 4 | 2.5 | 18 |
| Example 6 | Electrically conductive particles A1 | 5 | 4 | 5.0 | 18 |
| Example 7 | Electrically conductive particles A2 | 10 | 4 | 8.0 | 18 |
| Example 8 | Electrically conductive particles A2 | 10 | 4 | 17.0 | 140 |
| Example 9 | Electrically conductive particles B | 4 | 4.5 | 0.6 | 18 |
| Example 10 | Electrically conductive particles B | 4 | 4.5 | 2.5 | 18 |
| Example 11 | Electrically conductive particles B | 4 | 4.5 | 5.0 | 18 |
| Example 12 | Electrically conductive particles A2 | 10 | 4 | 3.1 | 12 |
| Example 13 | Electrically conductive particles A3 | 3 | 4 | 8.0 | 18 |
| Comparative Example 1 | Electrically conductive particles A1 | 5 | 4.5 | 20.0 | 175 |
| Comparative Example 2 | Electrically conductive particles A1 | 5 | 4.5 | 25.0 | 210 |
| Comparative Example 3 | Electrically conductive particles A1 | 5 | 4.5 | 27.0 | 210 |
| Comparative Example 4 | Electrically conductive particles A2 | 10 | 4 | 0.2 | 12 |

### Measurement of Connection Resistance

As a reference example, a circuit board (PWB) having three copper circuits with a line width of 1000 µm, a pitch of 10000 µm, and a thickness of 15 µm was bonded onto an epoxy substrate containing glass cloth by using the adhesive attached with the copper foil of each of Examples 1 to 13 and Comparative Examples 1 to 4. This product was heated and pressurized at 180° C. and 2 MPa for 10 seconds and connected over a width of 2 mm by using a thermocompression bonding apparatus (heating type: constant heating type, manufactured by Toray Engineering Co., Ltd.), thereby producing a connected body.

A sample in which a resist was formed on the produced connected body was immersed in an etching solution and shaken. The etching solution was prepared using copper chloride: 100 g/L and hydrochloric acid: 100 ml/L. When a predetermined copper foil portion was eliminated, washing with pure water was performed. Thereafter, the resist was released to obtain a desired evaluation sample. A resistance value between the copper foil portion remaining on the circuit and the copper circuit on the substrate was measured by a multimeter immediately after attachment and after storage in a high-temperature and high-humidity bath at 85° C. and 85% RH for 250 hours (after a test). The resistance value was shown as an average of resistance 37 points between the copper foil portion remaining on the circuit and the copper circuit on the substrate. Results of the resistance value are shown in Table 2.

TABLE 2

| | Average particle diameter (µm) | Surface roughness (µm) | Ratio of surface roughness/average particle diameter | Resistance value (Ω) (immediately after attachment) | Resistance value (Ω) (after 250 hours) |
|---|---|---|---|---|---|
| Example 1 | 10 | 0.6 | 0.06 | 0.03 | 0.04 |
| Example 2 | 10 | 2.5 | 0.25 | 0.03 | 0.04 |
| Example 3 | 10 | 5 | 0.5 | 0.02 | 0.05 |
| Example 4 | 5 | 0.6 | 0.12 | 0.04 | 0.07 |
| Example 5 | 5 | 2.5 | 0.5 | 0.06 | 0.06 |
| Example 6 | 5 | 5 | 1 | 0.05 | 0.06 |
| Example 7 | 10 | 8 | 0.8 | 0.04 | 0.08 |
| Example 8 | 10 | 17 | 1.7 | 0.04 | 0.06 |
| Example 9 | 4 | 0.6 | 0.15 | 0.03 | 0.05 |
| Example 10 | 4 | 2.5 | 0.625 | 0.02 | 0.04 |
| Example 11 | 4 | 5 | 1.25 | 0.03 | 0.06 |
| Example 12 | 10 | 3.1 | 0.31 | 0.03 | 0.05 |
| Example 13 | 3 | 8.0 | 2.67 | 0.07 | 0.09 |
| Comparative Example 1 | 5 | 20 | 4 | 0.11 | 0.52 |
| Comparative Example 2 | 5 | 25 | 5 | 0.23 | 0.66 |
| Comparative Example 3 | 5 | 27 | 5.4 | 0.29 | 0.59 |
| Comparative Example 4 | 10 | 0.2 | 0.02 | 0.05 | Unmeasurable |

As apparent from Table 2 above, it was confirmed that in Example 1 to Example 13, the resistance value is low in all cases, the electrically conductive particles are reliably crushed, and electrical conduction between wirings is more reliably performed and stabilized. On the other hand, it was considered that in Comparative Example 1 to Comparative Example 3, the resistance value is high, and the electrically conductive particles are not sufficiently crushed. Furthermore, in Comparative Example 4, the resistance value immediately after attachment is low, but adhesiveness cannot be maintained over a long period of time when the surface is too smooth, and the layers are peeled off from each other, which causes an unmeasurable state. As described above, it could be confirmed that by using the member for forming a wiring in which the ratio of the surface roughness Rz of the surface of the metal foil layer on a side attached to the adhesive layer with respect to the average particle diameter of the electrically conductive particles is 0.05 to 3, favorable connection can be secured even after a reliability test.

### REFERENCE SIGNS LIST

1, 1c, 1e: member for forming wiring, 1a, 1d, 1f: wiring layer, lb: wiring forming member, 10, 10c, 10d: adhesive layer, 10a: first surface, 10b: second surface, 10e: first adhesive layer, 10f: second adhesive layer, 12, 12a: electrically conductive particle, 14, 14a: adhesive layer, 20: metal foil layer, 20a: first surface, 20b: second surface.

1. A member for forming a wiring, comprising:
an adhesive layer formed from an adhesive composition including electrically conductive particles; and
a metal foil layer disposed on the adhesive layer,
wherein a ratio of surface roughness Rz of a surface of the metal foil layer on a side attached to the adhesive layer with respect to an average particle diameter of the electrically conductive particles is 0.05 to 3.

2. A member for forming a wiring, comprising:
an adhesive layer formed from an adhesive composition including electrically conductive particles; and
a metal foil layer disposed on the adhesive layer,
wherein surface roughness Rz of a surface of the metal foil layer on a side attached to the adhesive layer is less than 20 µm.

3. The member for forming a wiring according to claim 1, wherein the surface roughness Rz of the metal foil layer is 0.5 µm or more and 10 µm or less.

4. The member for forming a wiring according to claim 1, wherein an average particle diameter of the electrically conductive particles is 2 µm or more and 20 µm or less.

5. The member for forming a wiring according to claim 1, wherein a shortest distance between a surface, which is in contact with the adhesive layer, of the metal foil layer and the surface of the electrically conductive particle is more than 0 µm and 1 µm or less.

6. The member for forming a wiring according to claim 1, wherein the adhesive layer includes a first adhesive layer in which the electrically conductive particles are included in an adhesive component and a second adhesive layer, and the first adhesive layer is located between the metal foil layer and the second adhesive layer.

7. The member for forming a wiring according to claim 1, further comprising a release film.

8. A member for forming a wiring, comprising an adhesive layer formed from an adhesive composition including electrically conductive particles and a metal foil layer as separate bodies, the adhesive layer capable of being attached to the metal foil layer during use,
wherein a ratio of surface roughness Rz of a surface of the metal foil layer on a side attached to the adhesive layer with respect to an average particle diameter of the electrically conductive particles is 0.05 to 3, or
wherein surface roughness Rz of a surface of the metal foil layer on a side attached to the adhesive layer is less than 20 µm.

9. (canceled)

10. A method for forming a wiring layer, the method comprising:
preparing the member for forming a wiring according to claim 1;
preparing a base material on which a wiring is formed;
disposing the member for forming a wiring with respect to a surface of the base material on which a wiring is formed to cover the wiring so that the adhesive layer faces the base material;
heating and pressure-bonding the member for forming a wiring to the base material; and
subjecting the metal foil layer to a patterning treatment.

11. A wiring forming member comprising:
a base material having a wiring; and
a cured product of the member for forming a wiring according to claim 1, the cured product disposed on the base material to cover the wiring,
wherein the wiring is electrically connected to the metal foil of the member for forming a wiring or to another wiring formed from the metal foil.

12. The member for forming a wiring according to claim 2, wherein the surface roughness Rz of the metal foil layer is 0.5 µm or more and 10 µm or less.

13. The member for forming a wiring according to claim 2, wherein an average particle diameter of the electrically conductive particles is 2 µm or more and 20 µm or less.

14. The member for forming a wiring according to claim 2, wherein a shortest distance between a surface, which is in contact with the adhesive layer, of the metal foil layer and the surface of the electrically conductive particle is more than 0 µm and 1 µm or less.

15. The member for forming a wiring according to claim 2, wherein the adhesive layer includes a first adhesive layer in which the electrically conductive particles are included in an adhesive component and a second adhesive layer, and the first adhesive layer is located between the metal foil layer and the second adhesive layer.

16. The member for forming a wiring according to claim 2, further comprising a release film.

17. A method for forming a wiring layer, the method comprising:
preparing the member for forming a wiring according to claim 2;
preparing a base material on which a wiring is formed;
disposing the member for forming a wiring with respect to a surface of the base material on which a wiring is formed to cover the wiring so that the adhesive layer faces the base material;
heating and pressure-bonding the member for forming a wiring to the base material; and
subjecting the metal foil layer to a patterning treatment.

18. A method for forming a wiring layer, the method comprising:
preparing the member for forming a wiring according to claim 8;
preparing a base material on which a wiring is formed;
disposing the member for forming a wiring with respect to a surface of the base material on which a wiring is formed to cover the wiring so that the adhesive layer faces the base material;
heating and pressure-bonding the member for forming a wiring to the base material; and
subjecting the metal foil layer to a patterning treatment.

19. A wiring forming member comprising:
a base material having a wiring; and
a cured product of the member for forming a wiring according to claim 2, the cured product disposed on the base material to cover the wiring,
wherein the wiring is electrically connected to the metal foil of the member for forming a wiring or to another wiring formed from the metal foil.

20. A wiring forming member comprising:
a base material having a wiring; and
a cured product of the member for forming a wiring according to claim 8, the cured product disposed on the base material to cover the wiring,
wherein the wiring is electrically connected to the metal foil of the member for forming a wiring or to another wiring formed from the metal foil.
